(19) United States
(12) Patent Application Publication
(10) Pub. No.: US 2020/0409405 A1
(43) Pub. Date: Dec. 31, 2020

(54) VOLTAGE TRIMMING CIRCUIT AND VOLTAGE GENERATION CIRCUIT INCLUDING THE SAME

(71) Applicant: SK hynix Inc., Icheon-si (KR)

(72) Inventor: Chan Keun KWON, Yongin-si (KR)

(73) Assignee: SK hynix Inc., Icheon-si (KR)

(21) Appl. No.: 16/721,423

(22) Filed: Dec. 19, 2019

(30) Foreign Application Priority Data
Jun. 27, 2019 (KR) 10-2019-0076950

(51) Int. Cl. G05F 3/08

(52) U.S. Cl. CPC G05F 3/08; G11C 16/0483

(57) ABSTRACT

A voltage trimming circuit may include: a resistor array configured to divide a first voltage at different division ratios through output nodes, output the divided voltages, and change a resistance value based on one or more voltage level control signals; and a multiplexer configured to select one voltage level from the output nodes based on the remainder of the voltage level control signals and output a voltage level of the selected node as an output voltage.

### CROSS-REFERENCES TO RELATED APPLICATION

The present application claims priority under 35 U.S.C. § 119(a) to Korean application number 10-2019-0076950, filed on Jun. 27, 2019, in the Korean Intellectual Property Office, which is incorporated herein by reference in its entirety.

### BACKGROUND

### 1. Technical Field

Various embodiments generally relate to a semiconductor circuit, and particularly, to a voltage trimming circuit and a voltage generation circuit including the same.

### 2. Related Art

Semiconductor devices require various levels of voltages to perform various operations within the semiconductor devices.

In semiconductor devices, for example, a NAND flash memory requires voltages having different target levels based on the different operations that need to be performed, such as a program operation, a read operation, and a verify operation.

Semiconductor devices may generate various levels of voltages by using a voltage generation circuit.

### SUMMARY

In an embodiment, a voltage trimming circuit may include: a resistor array configured to divide a first voltage at different division ratios through output nodes, output the divided voltages, and change a resistance value based on one or more voltage level control signals; and a multiplexer configured to select a voltage level of one of the output nodes based on the remainder of the voltage level control signals and output the voltage level of the selected node as an output voltage.

In an embodiment, a voltage trimming circuit may include: a resistor array including a plurality of resistors electrically connected between a first terminal, through which a first voltage is outputted and a ground terminal, a first resistor selection switch electrically connected to both ends of one of the plurality of resistors, electrically connected to the first terminal, and a second resistor selection switch electrically connected to both ends of one of the plurality of resistors, electrically connected to the ground terminal, the first resistor selection switch and the second resistor selection switch being controlled based on one or more voltage level control signals; and a multiplexer, connected to output nodes of the resistor array, configured to select a voltage level of one of the output nodes of the resistor array based on the remainder of the voltage level control signals and output the voltage level of the selected node as an output voltage.

In an embodiment, a voltage generation circuit may include: a reference voltage generation circuit configured to generate a reference voltage; a differential amplifier configured to substantially maintain a first voltage at substantially the same level as the reference voltage; a resistor array configured to divide the first voltage at different division ratios through output nodes, output the divided voltages, and change a resistance value based on one or more voltage level control signals; and a multiplexer configured to select a voltage level of one of the output nodes based on the remainder of the voltage level control signals and output the voltage level of the selected node as an output voltage.

### BRIEF DESCRIPTION OF THE DRAWINGS

FIG. 1 is a diagram, illustrating a configuration of a voltage generation circuit, in accordance with an embodiment.

FIG. 2 is a diagram, illustrating a configuration of a voltage trimming circuit, in accordance with an embodiment.

FIG. 3 is a diagram, illustrating a configuration of a voltage trimming circuit, in accordance with another embodiment.

FIG. 4 and FIG. 5 are diagrams for explaining an operation of the voltage trimming circuit of FIG. 3.

### DETAILED DESCRIPTION

Hereinafter, a voltage trimming circuit and a voltage generation circuit including the same will be described in more detail with reference to the accompanying drawings.

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and the descriptions are not limited to the embodiments described in the present specification or application.

Since various modifications and changes may be applied to the embodiment according to the concept of the present disclosure and the embodiment according to the concept of the present disclosure may have various forms, the specific embodiments will be illustrated in the drawings and described in the present specification or application. However, it should be understood that the embodiment according to the concept of the present disclosure is not construed as limited to a specific disclosure form and includes all changes, equivalents, or substitutes that do not depart from the spirit and technical scope of the present disclosure.

While terms such as “first”, “second”, and/or the like may be used to describe various components, such components should not be limited to the above-described terms. The above-described terms may be used only to distinguish one component from another component. For example, a first component may be referred to as a second component and similarly, a second component may be referred to as a first component without departing from the scope according to the concept of the present disclosure.

It should be understood that when a component is referred to as being “connected” or “coupled” to another component, the component may be directly connected or coupled to the other element or an intervening component may also be present. In contrast, it should be understood that when a component is referred to as being “directly connected” or “directly coupled” to another component, no intervening component is present. Other expressions describing relationships between components such as “˜ between,” “immediately ˜ between” or “adjacent to ˜”, “directly adjacent to ˜”, and the like should be construed similarly.

The terms used in the present specification are merely used to describe a specific embodiment, and are not intended to limit the present disclosure. Singular expression includes a plural expression, unless the context clearly indicates otherwise. In the present specification, it should be understood that a term “include”, “have”, or the like indicates that a feature, a number, a step, an operation, a component, a part, or a combination thereof described in the present specification is present, but do not exclude a possibility of presence or addition of one or more other features, numbers, steps, operations, components, parts, or combinations thereof.

So far as not being differently defined, all terms used herein including technical or scientific terminologies have meanings that they are commonly understood by those skilled in the art to which the present disclosure pertains. The terms defined in generally used dictionaries should be construed as having the same meanings as would be construed in the context of the related art, and unless clearly defined otherwise in the present specification, should not be construed as having idealistic or excessively formal meanings.

A voltage trimming circuit capable of increasing a voltage level cover range by using a minimum circuit configuration and a voltage generation circuit including the same are described herein.

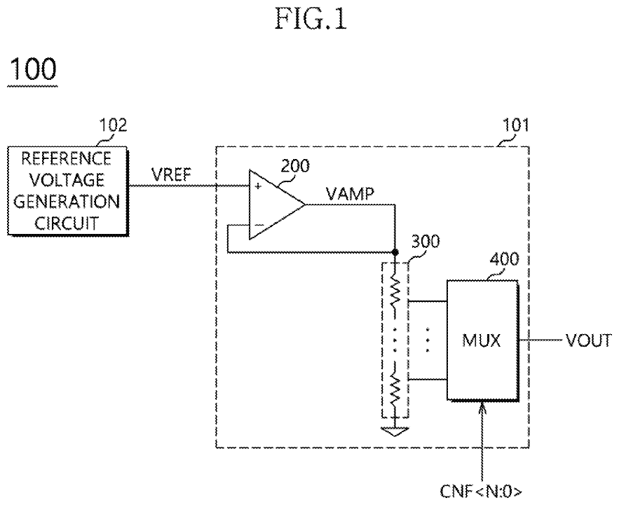

FIG. 1 is a diagram, illustrating a configuration of a voltage generation circuit in accordance with an embodiment.

Referring to FIG. 1, a voltage generation circuit 100, in accordance with an embodiment, may include a voltage trimming circuit 101 and a reference voltage generation circuit 102.

The voltage trimming circuit 101 may adjust the level of an output voltage VOUT to a target level, based on the reference voltage VREF and the voltage level control signals CNF<N:0>, and output the adjusted voltage.

The voltage trimming circuit 101 may include a differential amplifier 200, a resistor array 300, and a multiplexer (MUX) 400.

The differential amplifier 200 may receive the reference voltage VREF and its own output, that is, an amplified voltage VAMP, and substantially maintain the amplified voltage VAMP at substantially the same level as the reference voltage VREF.

The resistor array 300 may include a plurality of resistors electrically connected between a power supply terminal, that is, the output terminal of the amplified voltage VAMP of the differential amplifier 200, and a ground terminal.

The MUX 400 may select one of a plurality of nodes of the resistor array 300 based on the voltage level control signals CNF<N:0>, and output the voltage level of the selected node as the output voltage VOUT.

The reference voltage generation circuit 102 may generate the reference voltage VREF, having a constant level regardless of any temperature change.

The reference voltage generation circuit 102 may include a band gap reference circuit.

An operation of the voltage generation circuit 100, in accordance with the embodiment configured as described above, will be described as follows.

For example, it is assumed that a target level of the reference voltage VREF is 1.23 V and a target level of the output voltage VOUT is 1.0 V.

The voltage generation circuit 100 is ideally designed to generate the output voltage VOUT, having the target level (1.0 V) and various types of setting (for example, the values of the voltage level control signals CNF<N:0> are set).

However, the reference voltage VREF and the amplified voltage VAMP may be different from the target level due to a process difference and the like, and thus, the output voltage VOUT may be different from the target level.

Therefore, the voltage trimming circuit 101 may adjust the level of the output voltage VOUT to the target level, based on the adjustment of the voltage level control signals CNF<N:0>, to output an adjusted voltage.

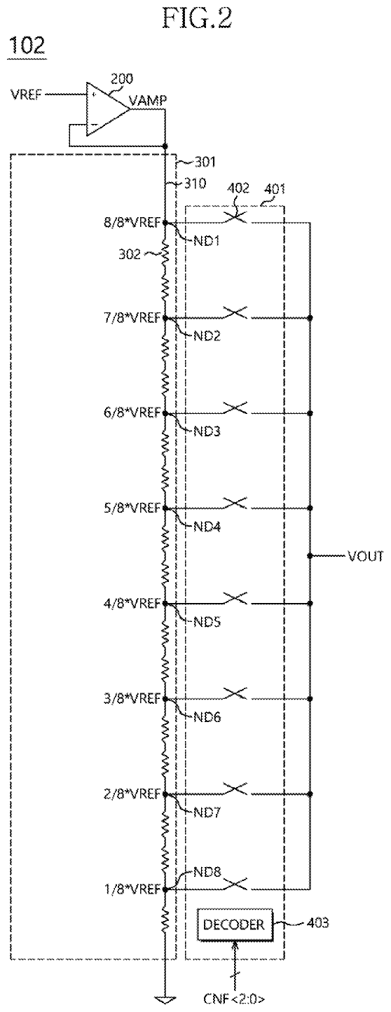

FIG. 2 is a diagram, illustrating a configuration of a voltage trimming circuit in accordance with the embodiment.

Referring to FIG. 2, a voltage trimming circuit 102, in accordance with the embodiment, may include a differential amplifier 200, a resistor array 301, and a multiplexer (MUX) 401.

The differential amplifier 200 may receive the reference voltage VREF and its own output, that is, an amplified voltage VAMP, and substantially maintain the amplified voltage VAMP at substantially the same level as the reference voltage VREF.

The resistor array 301 may include a plurality of resistors 302, electrically connected between a power supply terminal, that is, the output terminal of the amplified voltage VAMP of the differential amplifier 200 and a ground terminal.

The plurality of resistors 302 may have substantially the same resistance value.

Some of the nodes of the resistor array 301 may be referred to as output nodes, and voltages, obtained by dividing the amplified voltage VAMP at different division ratios, may be outputted through output nodes ND1 to ND8.

The voltage levels, outputted through the output nodes ND1 to ND8, may have values corresponding to 8/8*VREF, 7/8*VREF, 6/8*VREF, 5/8*VREF, 4/8*VREF, 3/8*VREF, 2/8*VREF, and 1/8*VREF in the order from the first output node ND1, closest to the output terminal of the amplified voltage VAMP, to the eighth output node ND8, closest to the ground terminal.

The MUX 401 may select one voltage level of the output nodes ND1 to ND8 of the resistor array 301, based on voltage level control signals CNF<2:0>, and output the voltage level of the selected node as an output voltage VOUT.

In order to select one of the output nodes ND1 to ND8, the voltage level control signals CNF<2:0> of 3 bits may be used.

The MUX 401 may include a plurality of voltage selection switches 402 and a decoder 403.

One end of each of the plurality of voltage selection switches 402 may be connected to each of the output nodes ND1 to ND8, and the other end, thereof, may be connected in common to the output voltage VOUT terminal.

The decoder 403 may decode the voltage level control signals CNF<2:0>, and connect one of the plurality of voltage selection switches 402 to the output voltage VOUT terminal, based on the decoding result.

One of the 8/8*VREF, 7/8*VREF, 6/8*VREF, 5/8*VREF, 4/8*VREF, 3/8*VREF, 2/8*VREF, and 1/8*VREF may be outputted as the output voltage VOUT, based on the values of the voltage level control signals CNF<2:0>.

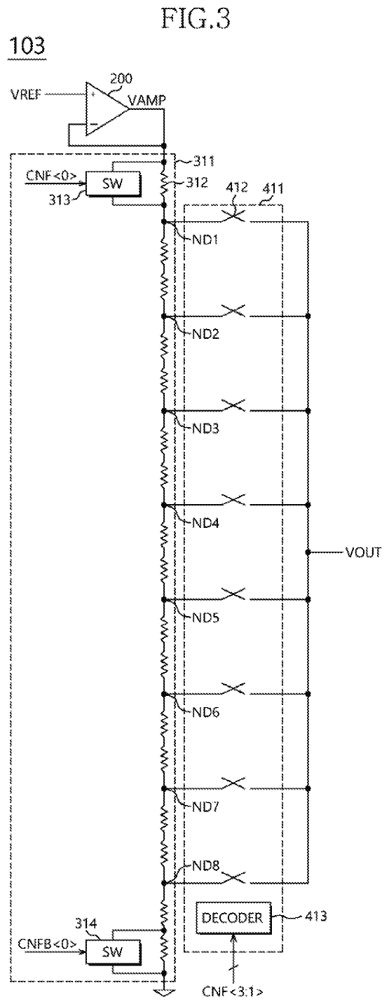

FIG. 3 is a diagram, illustrating a configuration of a voltage trimming circuit, in accordance with another embodiment.

Referring to FIG. 3, a voltage trimming circuit 103 in accordance with another embodiment may include a differential amplifier 200, a resistor array 311, and a multiplexer (MUX) 411.

The differential amplifier 200 may be configured to substantially maintain a first voltage, that is, an amplified voltage VAMP, which is its own output, at substantially the same level as a reference voltage VREF.

The differential amplifier 200 may receive the reference voltage VREF, through a non-inverting terminal (+) thereof, and an amplified voltage VAMP, through an inverting terminal (−) thereof.

The resistor array 311 may divide the amplified voltage VAMP at different division ratios through output nodes ND1 to ND8 and output the divided voltages.

In the resistor array 311, the resistance values of the resistor array 311 may be changed based on some of the voltage level control signals CNF<3:0>, such as, the least significant bit CNF<0> and a signal obtained by inverting the least significant bit CNF<0> (hereinafter, an inverted least significant bit CNFB<0>).

Although not illustrated in the drawing, the inverted least significant bit CNFB<0> may be generated by inverting the least significant bit CNF<0> through an inverter.

The resistor array 311 may include a plurality of resistors 312 and a plurality of resistor selection switches 313 and 314, electrically connected between a power supply terminal, that is, the output terminal of the amplified voltage VAMP of the differential amplifier 200 and a ground terminal.

The plurality of resistors 312 may have substantially the same resistance value.

Between the plurality of resistor selection switches 313 and 314, the first resistor selection switch 313 may be electrically connected to both ends of a resistor, which is directly connected to the output terminal of the amplified voltage VAMP, among the plurality of resistors 312.

The first resistor selection switch 313 may be turned on based on the least significant bit CNF<0>.

The second resistor selection switch 314 may be electrically connected to both ends of a resistor, which is directly connected to the ground terminal, among the plurality of resistors 312.

The second resistor selection switch 314 may be turned on based on the inverted least significant bit CNFB<0>.

The total resistance value of the resistor array 311 may be changed based on the value of the least significant bit CNF<0>, and thus voltage levels output through the output nodes ND1 to ND8 may also be changed.

That is, the voltage level of a node (for example, ND1) may have different values when the least significant bit CNF<0> is at a high level and when the least significant bit CNF<0> is at a low level.

The MUX 411 may select a voltage level of one of the output nodes ND1 to ND8 of the resistor array 311, based on the remaining CNF<3:1>, without the least significant bit CNF<0>, and output the voltage level of the selected node as an output voltage VOUT.

Since the amplified voltage VAMP is divided through the output nodes ND1 to ND8, the voltage level control signals CNF<3:1> of 3 bits may be used in order to select one of the output nodes ND1 to ND8.

The MUX 411 may include a plurality of voltage selection switches 412 and a decoder 413.

One end of each of the plurality of voltage selection switches 412 may be connected to each of the output nodes ND1 to ND8, and the other end thereof may be connected in common to the output voltage VOUT terminal.

The decoder 413 may decode the voltage level control signals CNF<3:1>, and connect one of the plurality of voltage selection switches 412 to the output voltage VOUT terminal based on the decoding result.

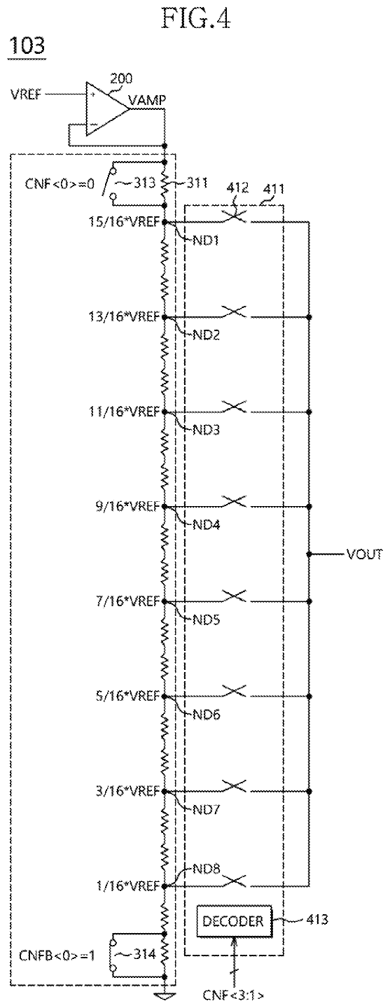

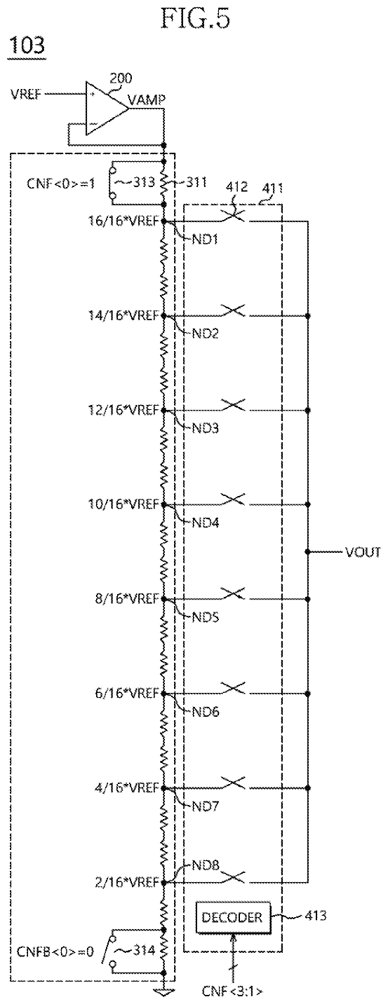

Hereinafter, an operation of the voltage trimming circuit 103, in accordance with another embodiment, will be described with reference to FIG. 4 and FIG. 5.

FIG. 4 and FIG. 5 are diagrams for explaining the operation of the voltage trimming circuit of FIG. 3, wherein FIG. 4 is a diagram for explaining the operation of the voltage trimming circuit 103 when the least significant bit CNF<0> of the voltage level control signals CNF<3:0> is 0, and FIG. 5 is a diagram for explaining the operation of the voltage trimming circuit 103 when the least significant bit CNF<0> of the voltage level control signals CNF<3:0> is 1.

Referring to FIG. 4, since CNF<0> is 0 and CNFB<0> is 1, the first resistor selection switch 313 is turned off, and the second resistor selection switch 314 is turned on.

The voltage levels outputted through the output nodes ND1 to ND8 may have values corresponding to 15/16*VREF, 13/16*VREF, 11/16*VREF, 9/16*VREF, 7/16*VREF, 5/16*VREF, 3/16*VREF, and 1/16*VREF in the order from the first output node ND1, closest to the output terminal of the amplified voltage VAMP, to the eighth output node ND8, closest to the ground terminal.

One of 15/16*VREF, 13/16*VREF, 11/16*VREF, 9/16*VREF, 7/16*VREF, 5/16*VREF, 3/16*VREF, and 1/16*VREF may be outputted as the output voltage VOUT, based on values of the voltage level control signals CNF<3:1>.

Referring to FIG. 5, since CNF<0> is 1 and CNFB<0> is 0, the first resistor selection switch 313 is turned on, and the second resistor selection switch 314 is turned off.

Since the first resistor selection switch 313 is turned on and the second resistor selection switch 314 is turned off, the resistance value from the eighth output node ND8 to the ground terminal increases as compared with the case of FIG. 4 (CNF<0> is 0 and CNFB<0> is 1). However, since the first output node ND1 is shorted from the amplified voltage VAMP, the resistance value of the resistor array 311 is the same.

Since the resistance value from the eighth output node ND8 to the ground terminal increases in the state in which the resistance value of the resistor array 311 is the same, the voltage levels outputted through the output nodes ND1 to ND8 increase based on the voltage division law.

The voltage levels outputted through the output nodes ND1 to ND8 may have values corresponding to 16/16*VREF, 14/16*VREF, 12/16*VREF, 10/16*VREF, 8/16*VREF, 6/16*VREF, 4/16*VREF, and 2/16*VREF in the order from the first output node ND1 closest to the output terminal of the amplified voltage VAMP to the eighth output node ND8 closest to the ground terminal.

One of 16/16*VREF, 14/16*VREF, 12/16*VREF, 10/16*VREF, 8/16*VREF, 6/16*VREF, 4/16*VREF, and 2/16*VREF may be outputted as the output voltage VOUT based on values of the voltage level control signals CNF<3:1>.

In another embodiment, as the values of the voltage level control signals CNF<3:0> are adjusted, for example, as ‘0000’ is adjusted to ‘1111’, one of 16/16*VREF, 15/16*VREF, 14/16*VREF, 13/16*VREF, 12/16*VREF, 11/16*VREF, 10/16*VREF, 9/16*VREF, 8/16*VREF, 7/16*VREF, 6/16*VREF, 5/16*VREF, 4/16*VREF, 3/16*VREF, 2/16*VREF, and 1/16*VREF may be outputted as the output voltage VOUT.

As described with reference to FIG. 4 and FIG. 5, another embodiment, based on FIG. 3, uses one more bit as the voltage level control signal and can be implemented with a voltage level cover range twice as large as that of FIG. 2 or at intervals 0.5 times more compact than that of FIG. 2, by changing the configuration of the resistor array 311, so that it is possible to more accurately adjust the level of the output voltage VOUT to a target level.

While various embodiments have been described above, it will be understood to those skilled in the art that the embodiments described are examples only. Accordingly, the voltage trimming circuit and the voltage generation circuit including the same described herein should not be limited based on the described embodiments.

What is claimed is:

1. A voltage trimming circuit comprising:
a resistor array configured to divide a first voltage at different division ratios through output nodes, output the divided voltages, and change a resistance value based on one or more voltage level control signals; and
a multiplexer configured to select a voltage level of one of the output nodes based on a remainder of the voltage level control signals and output the voltage level of the selected node as an output voltage.

2. The voltage trimming circuit according to claim 1, further comprising:
a differential amplifier configured to substantially maintain the first voltage at substantially the same level as a reference voltage.

3. The voltage trimming circuit according to claim 1, wherein the resistor array comprises:
a plurality of resistors, electrically connected between a terminal, through which the first voltage is outputted, and a ground terminal; and
a resistor selection switch, electrically connected to both ends of at least one of the plurality of resistors, and controlled based on the one or more voltage level control signals.

4. The voltage trimming circuit according to claim 1, wherein the multiplexer comprises:
a plurality of voltage selection switches, each having one end, electrically connected to each of the output nodes, and the other end, connected, in common, to a terminal, through which the output voltage is outputted; and
a decoder configured to decode the remainder of the voltage level control signals and connect one of the plurality of voltage selection switches to the terminal, through which the output voltage is outputted, based on a result of the decoding.

5. A voltage trimming circuit comprising:
a resistor array including a plurality of resistors, electrically connected between a first terminal, through which a first voltage is outputted, and a ground terminal, a first resistor selection switch, electrically connected to both ends of one of the plurality of resistors, electrically connected to the first terminal, and a second resistor selection switch, electrically connected to both ends of one of the plurality of resistors, electrically connected to the ground terminal, the first resistor selection switch and the second resistor selection switch being controlled based on one or more voltage level control signals; and
a multiplexer, connected to output nodes of the resistor array, configured to select a voltage level of one of the output nodes of the resistor array based on a remainder of the voltage level control signals and output the voltage level of the selected node as an output voltage.

6. The voltage trimming circuit according to claim 5, further comprising:
a differential amplifier configured to substantially maintain the first voltage at substantially the same level as a reference voltage.

7. The voltage trimming circuit according to claim 5, wherein the first resistor selection switch is controlled based on a least significant bit of the voltage level control signals and the second resistor selection switch is controlled based on a signal, obtained by inverting the least significant bit.

8. The voltage trimming circuit according to claim 5, wherein the multiplexer comprises:
a plurality of voltage selection switches, each having one end, electrically connected to each of the output nodes, and the other end, connected, in common, to a terminal, through which the output voltage is outputted; and
a decoder configured to decode the remainder of the voltage level control signals and connect one of the plurality of voltage selection switches to the terminal, through which the output voltage is outputted, based on a result of the decoding.

9. A voltage generation circuit comprising:
a reference voltage generation circuit configured to generate a reference voltage;
a differential amplifier configured to substantially maintain a first voltage at substantially the same level as the reference voltage;
a resistor array configured to divide the first voltage at different division ratios through output nodes, output the divided voltages, and change a resistance value based on one or more voltage level control signals; and
a multiplexer configured to select a voltage level of one of the output nodes based on a remainder of the voltage level control signals and output the voltage level of the selected node as an output voltage.

10. The voltage generation circuit according to claim 9, wherein the resistor array comprises:
a plurality of resistors, electrically connected between a first terminal, through which the first voltage is outputted, and a ground terminal; and
a resistor selection switch, electrically connected to both ends of at least one of the plurality of resistors, and controlled by the one or more voltage level control signals.

11. The voltage generation circuit according to claim 9, wherein the resistor array comprises:
a plurality of resistors, electrically connected between a first terminal, through which the first voltage is outputted, and a ground terminal;
a first resistor selection switch, electrically connected to both ends of one resistor of the plurality of resistors, electrically connected to the first terminal; and
a second resistor selection switch electrically connected to both ends of one resistor of the plurality of resistors, electrically connected to the ground terminal,
wherein the first resistor selection switch and the second resistor selection switch are controlled by the one or more voltage level control signals.

12. The voltage generation circuit according to claim 11, wherein the first resistor selection switch is controlled based on a least significant bit of the voltage level control signals and the second resistor selection switch is controlled based on a signal obtained by inverting the least significant bit.

13. The voltage generation circuit according to claim 9, wherein the multiplexer comprises:
a plurality of voltage selection switches, each having one end, electrically connected to each of the output nodes, and the other end, connected, in common, to a terminal, through which the output voltage is outputted; and
a decoder configured to decode the remainder of the voltage level control signals and connect one of the plurality of voltage selection switches to the terminal, through which the output voltage is outputted, based on a result of the decoding.
